(19) United States
(12) Patent Application Publication
(10) Pub. No.: US 2019/0252256 A1
(43) Pub. Date: Aug. 15, 2019

(54) NON-LEADED DEVICE SINGULATION

(71) Applicant: NXP B.V., Eindhoven (NL)

(72) Inventors: Pimpa Boonyatee, Bangkok (TH); Ekapong Tangpattanasaeree, Bangkok (TH); Pitak Seantumpol, Pathumthani (TH)

(21) Appl. No.: 15/896,090

(22) Filed: Feb. 14, 2018

(51) Int. Cl. H01L 21/82; H01L 23/498; H01L 23/495

(52) U.S. Cl. CPC H01L 21/82; H01L 23/49838; H01L 23/49582; H01L 23/49866; H01L 23/49541

(57) ABSTRACT

A method of singulating no-lead semiconductor devices assembled on a lead frame array, includes performing first and second laser scribing operations first and second sides of saw streets of the lead frame array, and then cutting between the first and second scribe lines, formed by the scribing operations, with a saw. The finished devices include a notch, formed by the scribing operations, at exposed portions of the device leads. Scribing the saw streets before cutting prevents smearing of the leads and the formation of burrs on the leads.

### BACKGROUND

The present invention generally relates to non-leaded semiconductor devices, and, more particularly, to a method of singulating non-leaded devices.

Leaded semiconductor devices have leads that extend from a main package body. Non-leaded devices, such as Quad Flat No-leads (QFN) devices, are similar to leaded semiconductor devices except that the leads do not extend outwardly or project from the package body. Rather, the leads are generally flush with the package body. Non-leaded devices have become very popular because they have a smaller footprint than traditional leaded devices. Non-leaded devices also require fewer backend process steps since the leads do not need to be formed or bent, such as into a gull wing shape. However, because the leads lie in the same plane as the package body, burrs on the lead ends, formed during singulation (when the package is separated from an adjacent, simultaneously formed package), can cause issues for proper Printed Circuit Board (PCB) mounting. Another issue caused during singulation is smearing of the metal of the leads. Smearing is caused by the heat and friction from the saw blade, and is a problem because, in some cases, smearing can cause shorting between adjacent leads.

Accordingly, it would be advantageous to be able to singulate adjacent, simultaneously assembled devices without forming burrs on the leads or lead tips, or smearing the metal of the leads.

### BRIEF DESCRIPTION OF THE DRAWINGS

So that the manner in which the features of the present invention can be understood in detail, a detailed description of the invention is provided below with reference to embodiments, some of which are illustrated in the appended drawings. It is to be noted, however, that the appended drawings illustrate only typical embodiments of the invention and are therefore not to be considered limiting of its scope, for the invention may admit to other equally effective embodiments. The drawings are for facilitating an understanding of the invention and thus are not necessarily drawn to scale, and some features may be omitted in order to highlight other features of the invention so that the invention may be more clearly understood. Advantages of the subject matter claimed will become apparent to those skilled in the art upon reading this description in conjunction with the accompanying drawings, in which like reference numerals have been used to designate like elements, and in which:

FIG. 1 is an enlarged top plan view of a portion of a lead frame strip including an array of partially assembled semiconductor devices;

FIGS. 2A, 2B and 2C are greatly enlarged front views of a cross-section of portions of two adjacent semiconductor devices during a singulating operation in accordance with an embodiment of the present invention;

FIGS. 3A, 3B and 3C are greatly enlarged front views of a cross-section of portions of two adjacent semiconductor devices during a singulating operation in accordance with another embodiment of the present invention;

FIG. 4 is an enlarged photograph of a portion of a lead frame assembly after a scribing operation performed in accordance with an embodiment of the present invention; and

FIG. 5 is an enlarged perspective view of a QFN device cut from an array in accordance with an embodiment of the present invention.

### DETAILED DESCRIPTION

In one embodiment, the present invention provides a no-leads semiconductor device, such as a Quad Flat No-leads (QFN) device. The device includes an integrated circuit (IC) die, and a plurality of lead fingers spaced from and projecting outwardly from at least one side of the IC die. Electrodes of the IC die are electrically connected to proximal portions of respective ones of the lead fingers. A housing encases the IC die, the lead fingers, and the connections therebetween. The housing has opposing top and bottom surfaces, and side surfaces that extend between the top and bottom surfaces. Distal ends of the leads are exposed at the bottom and the at least one side surface of the housing, and the exposed distal ends are flush with the bottom surface. There also is a first notch in the exposed portions of each of the leads. The first notch offsets a portion of the distal end of the lead from the side surface. The notch is formed as a consequence of scribing saw streets of simultaneously assembled devices prior to singulating the devices.

In another embodiment, the present invention provides a method of singulating no-lead semiconductor devices assembled on a lead frame array. The method includes performing a first scribing operation on a first side of a saw street of the lead frame array, thereby forming a first scribe line, and performing a second scribing operation on a second side of the saw street, thereby forming a second scribe line. Cutting between the first and second scribe lines is then performed with a saw, thereby separating adjacent, simultaneously formed no-lead semiconductor devices. The first and second scribing operations form a notch in exposed portions of the leads at edges of the devices.

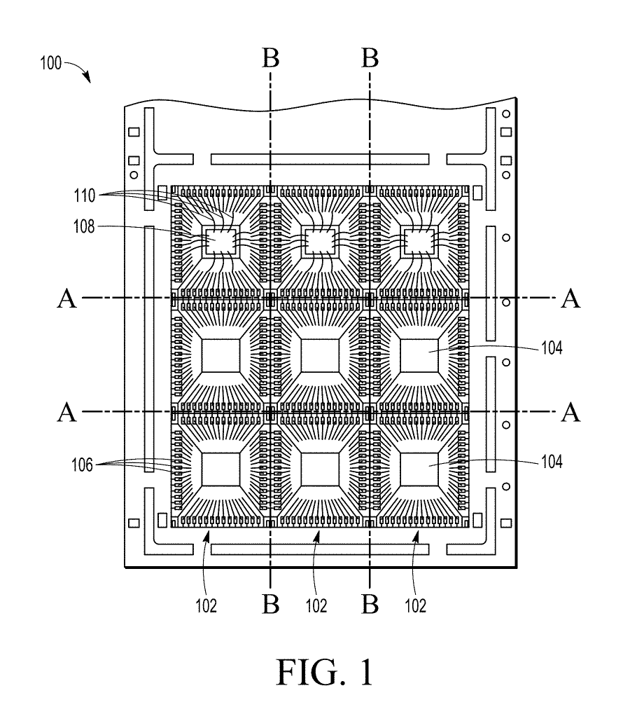

Referring now to FIG. 1, an enlarged top plan view of portion of a lead frame strip 100 for assembling a plurality of semiconductor devices is shown. The lead frame strip 100 includes a plurality of interconnected lead frames 102 arranged in an array, such as a “n”×“m” array, where n is the number of rows and m is the number of columns. FIG. 1 shows a nine (9) lead frames 102 arranged in a 3×3 array. The lead frame strip 100 typically is formed of copper that is plated or partially plated with a metal or metal alloy, such as tin, nickel, and/or palladium, which inhibits corrosion and provides for a good, solderable surface. In the presently preferred embodiment, the lead frames 102 are comprised of copper, and at least the leads are plated with a non-corroding material, such as nickel and palladium.

As is known in the art, to assemble a semiconductor device, an integrated circuit die is attached to a die receiving area of a lead frame and then the die is electrically connected to leads or lead fingers of the lead frame, such as with bond wires or flip-chip interconnects. Then the assembly is covered with a molding compound. Using the lead frame strip 100, a plurality of semiconductor devices may be simultaneously assembled. After molding, singulation is performed to separate the devices from each other. Singulation is performed by cutting with a saw blade along saw streets, which in FIG. 1 are labeled as A-A and B-B. Unfortunately, as explained above, saw singulation can cause burrs and lead smearing. Therefore, the inventors have developed a method for singulating adjacent devices that does not cause or limits the formation of burrs and lead smearing.

The lead frames 102 each comprise a central die receiving area 104, e.g., a die pad that is sized and shaped to receive a semiconductor die and thus, the size of the die pad generally is based on the size of the die. In the embodiment shown, the die pad 104 is rectangular, but this is not a requirement. The lead frames 102 also have a plurality of leads 106 that extend away from at least one lateral side of the central area or die pad 104. In the embodiment shown, the leads 106 surround the die pad 104 and extend away from all four lateral sides of the die pad 104. However, as will be understood by those of skill in the art, the leads 106 may extend from just two opposing lateral sides of the die pad 104. The leads 106 each have a proximal end near to but spaced from the die pad 104 and a distal end 112 that is connected to a lead of an adjacent lead frame (at a saw street) if there is one, or to a part of the frame of the lead frame strip 100 (which also would be at a saw street).

Integrated circuit dies 108 are attached to the die pads 104 during the assembly process. The dies 104 are attached to the die pads 104 of the lead frames 102 using a die attach material, such as an adhesive or adhesive tape, as is known in the art. In one embodiment, the adhesive is thermally conductive, so that heat generated by the semiconductor die 108 can be dissipated through the die pad 104. In another embodiment, the adhesive is both electrically and thermally conductive for providing additional connection between the semiconductor die 108 and the die pad 104. In one embodiment, the adhesive comprises an epoxy paste that is printed onto the die pad 104. After the semiconductor die 108 is attached to the die pad 104, the adhesive is cured so that the semiconductor die 108 is securely fastened to the die pad 104.

The semiconductor die 108 may be any type of die, such as a sensor die, a power die, an application specific integrated circuit (ASIC), etc. The semiconductor die 108 may have an active region on one side thereof and a non-active region on an opposite side. In the presently preferred embodiment, the semiconductor die 108 is placed on the die pad 104 such that the non-active region side faces the die pad 104. In another embodiment, the active region side of the semiconductor die 108 can be configured to face the die pad 104 and connect to the leads 106 with bumps or flip-chip connections.

When the semiconductor die 108 is mounted on the die pad 104 with its non-active region side attached to the die pad 104, then bond wires 110 are used to electrically connect the semiconductor die 108 to the proximal ends of the leads 106. That is, the electrodes on the active side surface of the semiconductor die 108 are electrically connected to the proximal ends of the leads 106 with the bond wires 110. The bond wires 110 can be any kind of bond wires, such as copper or gold, and may be coated or uncoated.

After attaching and electrically connecting the semiconductor dies 108 to the lead frames 102, the dies 108, bond wires 110 and at least the proximal ends of the leads 106 are covered with a molding compound (not shown in FIG. 1). When simultaneously assembling a plurality of semiconductor devices, the mold molding compound covers all of the dies 108 and lead frames 102. The molding compound provides electrical and mechanical protection to the semiconductor die 108, the lead frame 102 and the connections 110 therebetween. In one embodiment, the molding compound comprises an epoxy-resin composition, for example a C-stage plastic material (Resite). The molding compound subsequently is cured to be physically hard, so that the semiconductor die 108, the leads 106, and the bond wires 110 covered by the molding compound are protected from potential environmental influences like moisture and dust, as well as mechanical damage. The molding compound may be formed over the dies 108 using known methods, such as transfer molding.

After molding, the lead frame strip 100 is singulated, whereby the assemblies are separated and the frame is cut away by cutting along the saw streets A-A and B-B. Additional saw streets cutting the frame away are not shown just for the sake of clarity.

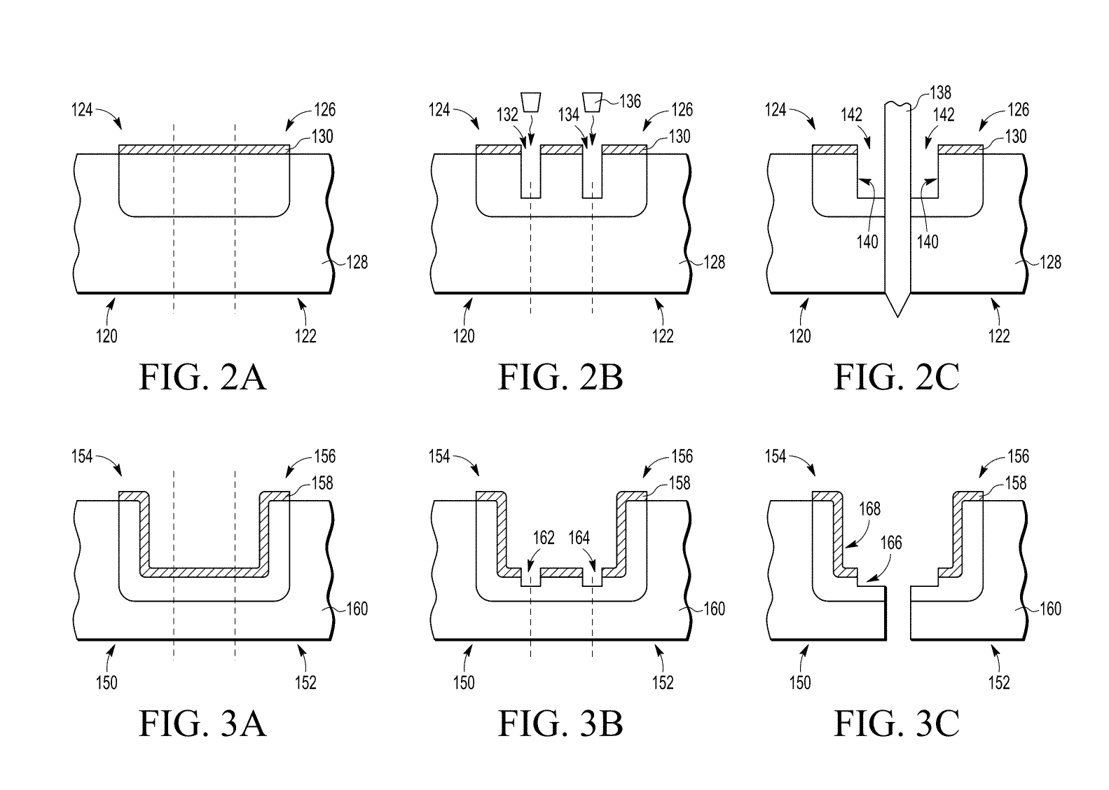

Referring now to FIGS. 2A, 2B and 2C, greatly enlarged front views of a cross-section of portions of two adjacent semiconductor devices 120 and 122 during a singulating operation in accordance with an embodiment of the present invention are shown. FIG. 2A shows the devices 120 and 122 before a singulation operation. The semiconductor devices 120 and 122 have respective leads 124 and 126, which at this stage, are joined together at one of the saw streets A-A or B-B shown in FIG. 1, where the saw street here is denoted by the pair of vertical dashed lines. The devices 120 and 122 also are covered with common mold compound 128. In addition, the exposed surfaces of the leads 124 and 126 are plated with a metal such as Tin and/or Palladium.

FIG. 2B illustrates first and second scribing operations being performed on first and second sides of the saw street. The first and second scribing operations form respective first and second scribe lines 132 and 134. The first and second scribing operations are performed with a laser 136. The laser 136 may be a fiber laser, a diode laser, a CO2 laser, or the like, with a laser power of 1-20 W at 1-1000 mm/s. The first and second scribing operations preferably are performed at the edges of the saw street, and form the scribe lines 132 and 134, which essentially are channels or grooves cut into the leads 124 and 126. Preferably the scribe lines 132 and 134 are made at the outer edges of the saw street. The first and second scribing operations cut into exposed portions of the leads 124 and 126 to a first depth thereof, where the first depth is 0.01% to 90% of the package thickness. In one embodiment, the first depth is one-half or more than one-half of a thickness of the leads 124 and 126. In another embodiment, the first depth is the entire thickness of the leads 124, 126, such that the bottom of the groove formed by the scribing operations exposes the mold compound 128 beneath the leads 124 and 126. A width of the scribe lines 132 and 134 may be from 0.01 mm to about 1 mm. A distance between the scribe lines 132 and 134 may be between 30 um and 1.0 mm, and in one embodiment, the distance between the scribe lines 132 and 134 is just less than a width of the saw blade (FIG. 2C, #138) used to complete the singulation operation.

FIG. 2C shows a cutting operation being performed in the saw street and within the first and second scribe lines 132 and 134 with a saw blade 138, which separates the adjacent, simultaneously formed no-lead semiconductor devices 120 and 122. That is, the saw blade 138 cuts all the way through the common portion of the leads 124, 126 and the mold compound 128. Preferably, the saw blade 138 has a thickness that is less than the entire width measured from one scribe line to the other scribe line such that the saw blade 138 cuts away the material in the saw street and between the scribe lines 132, 134, but does not touch side walls 140 of the scribe lines 132, 134. The cutting operation may be performed, for example, using a resin blade, a metal sintered blade, a nickel blade, or the like, having a thickness of 25 um to 90 um, as are known in the art. The saw blade 138 is centered between the scribe lines 132, 134, and the saw is operated at a speed of 1-100 mm/sec with a blade cut depth that is greater than the overall package thickness (e.g., 100 um to 1 mm).

The scribing and cutting operations form a first notch 142 in the lateral side wall of the finished devices 120 and 122. The distal ends of the leads 124 and 126 are exposed at and flush with the bottom surface of the finished devices 120 and 122. Further, the lateral side walls of the finished devices 120 and 122, include exposed portions of the leads 124 and 126, and the first notch 142. The first notchs 142 offset a portion of the distal ends of the leads 124 and 126 from the side surface of the devices 120 and 122. It also should be noted that an exposed surface of each of the leads 124 and 126 at the side surface of the housing is not plated with a metal or metal alloy, as the inner portions of the leads, now exposed, were not plated. Of course, as will be understood by those of skill in the art, the exposed portions of the underlying Copper could be plated after singulation.

FIGS. 3A, 3B and 3C are greatly enlarged front views of a cross-section of portions of two adjacent semiconductor devices during a singulating operation in accordance with another embodiment of the present invention.

FIG. 3A shows two adjacent semiconductor devices 150 and 152 prior to a singulating operation, such that the devices 150 and 152 are joined at a saw street, which is denoted with the dashed lines. In this embodiment, the leads are grooved so that the saw has less metal to cut, which makes sawing easier and there is less wear on the saw blade so the blade last longer. The first device 150 has a lead 154 and the second device has a lead 156, both of which are plated with a metal or metal alloy 160 to prevent exposure of the underlying copper. The devices 150 and 152 also are covered with a common mold compound 160.

FIG. 3B shows the devices 150 and 152 are first and second scribing operations have been performed on first and second sides of the saw street. The first and second scribing operations form respective first and second scribe lines 162 and 164. The first and second scribing operations are performed with a laser, as described above with reference to FIG. 2B. The first and second scribing operations preferably are performed at the edges of the saw street, again as described with reference to FIG. 2B, forming the scribe lines 162 and 164, which essentially are channels or grooves cut into the leads 154 and 156. Preferably the scribe lines 162 and 164 are made at the outer edges of the saw street. The first and second scribing operations cut into exposed portions of the leads 154 and 156 to a first depth thereof. In this embodiment, the laser does not have to cut as deep as in the previously described embodiment because the metal of the leads 154 and 156 is thinner than the metal of the leads 124 and 126. Still though, it is preferred that the depth of the scribe lines 162, 164 is one-half or more of a thickness of the leads 154 and 156. However, in one embodiment, the lasers cut entirely through the metal of the leads 154 and 156 and expose the underlying molding compound 160.

FIG. 3C shows the two devices 150 and 152 after a cutting operation with a saw blade has been performed. The cutting operation uses a saw blade to cut through the mold compound 160 and the portions of the leads 154 and 156 that are lie in the saw street, thereby forming no-lead semiconductor devices. Preferably the saw blade cuts along the saw street and partially in the grooves of the scribe lines 162, 164, but does not touch the sides of the finished leads 154 and 156 so that no lead smearing is caused. That is, preferably, the saw blade has a thickness that is less than the entire width measured from one scribe line 162 to the other scribe line 164 such that the saw blade 138 cuts away the material in the saw street and between the scribe lines 162, 164, but does not touch side walls of the scribe lines. The cutting operation is performed using a saw as described above with reference to FIG. 2C.

The scribing and cutting operations form a first notch 166 in the lateral side wall of the finished devices. Further, since in this embodiment, the saw street part of the leads 154 and 156 already included a channel so the saw blade would not have to cut through so much metal, the finished devices 150 and 152 have a second notch 168. Thus, where the leads 154 and 156 generally are flush with the bottom surface of the devices 150, 152, respectively, the exposed portions of the leads 154 and 156 on the device sidewalls include the first and second notches 166 and 168.

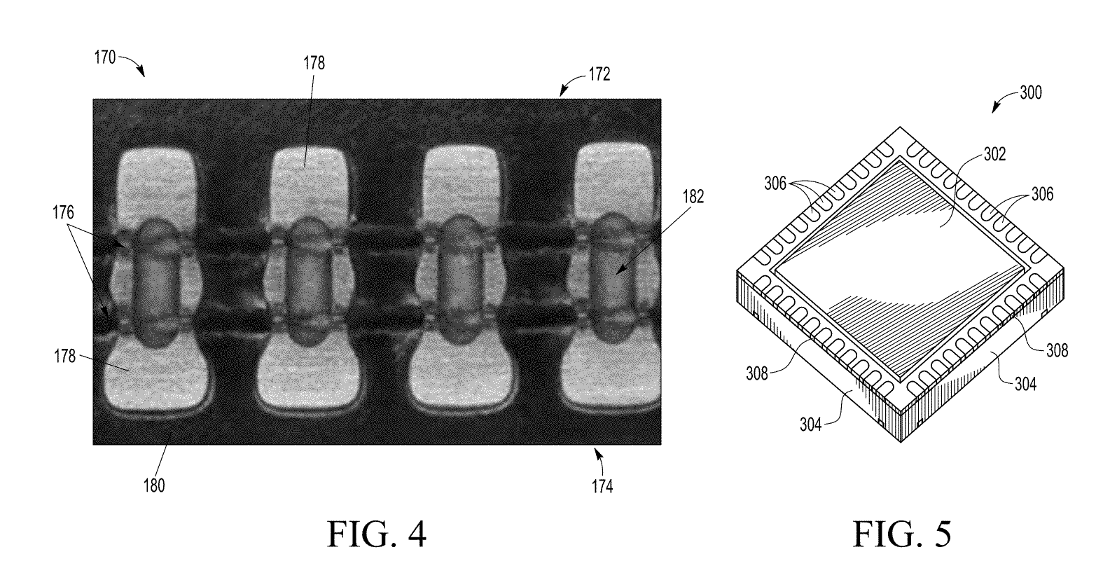

FIG. 4 is an enlarged photograph of a portion of a lead frame assembly 170 after a scribing operation performed in accordance with an embodiment of the present invention. The photograph shows portions of two devices 172 and 174 after scribing, but before singulation. Thus, two parallel scribe lines 176 are formed in the leads 178 and the mold compound 180. The leads 178, at least in the saw street, have cavities 182 where portions of the metal were etched away prior to assembly, which, after cutting, allows for a wettable surface that allows for a good solder joint.

FIG. 5 is an enlarged perspective view of a semiconductor device 300 in accordance with an embodiment of the present invention. The semiconductor device 300 comprises a molded body having a bottom surface 302, side surfaces 304, and a top surface that opposes the bottom surface but is not visible in FIG. 5. The device has leads 306 that are exposed at the bottom and side surfaces 302 and 304. The leads 306 are flush or co-planar with the bottom surface 302. The side surfaces 304, however, include a notch 308 that is formed by the scribe lines that are formed when performing a singulating operation in accordance with the present invention, where the singulation operation includes first and second scribing operations and then a singulating operation.

The use of the terms “a” and “an” and “the” and similar referents in the context of describing the subject matter (particularly in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

Furthermore, the foregoing description is for the purpose of illustration only, and not for the purpose of limitation, as the scope of protection sought is defined by the claims as set forth hereinafter together with any equivalents thereof entitled to. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

Preferred embodiments are described herein, including the best mode known to the inventor for carrying out the claimed subject matter. Of course, variations of those preferred embodiments will become apparent to those of ordinary skill in the art upon reading the foregoing description. The inventor expects skilled artisans to employ such variations as appropriate, and the inventor intends for the claimed subject matter to be practiced otherwise than as specifically described herein. Accordingly, this claimed subject matter includes all modifications and equivalents of the subject matter recited in the claims appended hereto as permitted by applicable law. Moreover, any combination of the above-described elements in all possible variations thereof is encompassed unless otherwise indicated herein or otherwise clearly contradicted by context.

1. A no-leads semiconductor device, comprising:
an integrated circuit (IC) die;
a plurality of lead fingers spaced from and projecting outwardly from at least one side of the IC die, wherein electrodes of the IC die are electrically connected to proximal portions of respective ones of the lead fingers;
a housing encasing the IC die, the lead fingers, and connections therebetween, wherein the housing has opposing top and bottom surfaces, and side surfaces that extend between the top and bottom surfaces,
wherein distal ends of the lead fingers are exposed at the bottom and at least one of the side surfaces of the housing, and the exposed distal ends are flush with the bottom surface,
wherein an exposed portion of each of the lead fingers includes a first notch that offsets a portion of the distal ends of the lead fingers from the at least one of the side surfaces; and
a second notch formed in the exposed portions of the lead fingers and the housing, and
wherein the first and second notches extend along the at least one of the side surfaces of the housing.

2. (canceled)

3. (canceled)

4. The no-leads semiconductor device of claim 7, wherein the plating comprises nickel and palladium.

5. The no-leads semiconductor device of claim 1, wherein the first notch is formed by scribing the lead fingers prior to singulating the device.

6. (canceled)

7. The no-leads semiconductor device of claim 1, wherein the exposed distal ends each of the lead fingers that is flush with the bottom surface of the housing is plated with a metal or metal alloy.

8. The no-leads semiconductor device of claim 7, wherein a first vertical surface of the exposed portion of each of the lead fingers also is plated with the metal or the metal alloy.

9. The no-leads semiconductor device of claim 5, wherein the second notch is formed by singulating the device.

10. The no-leads semiconductor device of claim 9, wherein inner surfaces of the distal ends of the lead fingers formed by the first notch are not plated with the metal or the metal alloy.

11. (canceled)

12. (canceled)

13. (canceled)

14. (canceled)

15. (canceled)

16. (canceled)
